(19) United States
(12) Patent Application Publication
(10) Pub. No.: US 2014/0096807 A1
(43) Pub. Date: Apr. 10, 2014

(54) THERMOELECTRIC ASSEMBLY USING A CARTRIDGE SUPPORT FIXTURE

(71) Applicant: Gentherm Incorporated, Northville, MI (US)

(72) Inventor: Marco Ranalli, Augsburg (DE)

(73) Assignee: Gentherm Incorporated, Northville, MI (US)

(21) Appl. No.: 14/041,037

(22) Filed: Sep. 30, 2013

Related U.S. Application Data
(60) Provisional application No. 61/709,463, filed on Oct. 4, 2012.

(51) Int. Cl. H01L 35/02; H01L 35/34

(52) U.S. Cl. CPC H01L 35/02; H01L 35/34
USPC 136/205; 438/55

(57) ABSTRACT

A thermoelectric power generator (TEG) assembly and a method of fabrication are provided. The TEG assembly includes at least one thermoelectric (TE) module, a casing containing the at least one TE module, and at least one support fixture mechanically coupling the at least one TE module to the casing. The at least one support fixture is coupled to the at least one TE module. The at least one portion of the at least one TE module is configured to move relative to the casing in response to temperature-induced dimensional changes of at least a portion of the at least one TE module or at least a portion of the casing.

### RELATED APPLICATIONS

This application claims the benefit of U.S. Provisional Application No. 61/709,463, filed Oct. 4, 2012 and the entire contents of which is incorporated by reference herein and made a part of this specification.

### BACKGROUND

1. Field

The present application relates generally to thermoelectric cooling, heating, and power generation systems.

2. Description of Related Art

Thermoelectric (TE) devices and systems can be operated in either heating/cooling or power generation modes. In the former, electric current is passed through a TE device to pump the heat from the cold side to the hot side. In the latter, a heat flux driven by a temperature gradient across a TE device is converted into electricity. In both modalities, the performance of the TE device is largely determined by the figure of merit of the TE material and by the parasitic (dissipative) losses throughout the system. Working elements in the TE device are typically p-type and n-type semiconducting materials.

Thermoelectric generator (TEG) modules (e.g., cartridges) can be welded to the casing (e.g., canning) containing the module in order to ensure a desired holding and gas tightness function. The weld seam between the casing and the module is conventionally applied to the module ends (e.g., end-caps). The welding operation is generally very delicate due to the temperature sensitivity of the materials around the ends and can be time consuming (e.g., it is performed twice for each module, once at each end).

### SUMMARY

In certain embodiments, a thermoelectric power generator (TEG) assembly is provided. The TEG assembly comprises at least one thermoelectric (TE) module, a casing containing the at least one TE module, and at least one support fixture mechanically coupling the at least one TE module to the casing. The at least one support fixture is coupled to the at least one TE module. The at least one portion of the at least one TE module is configured to move relative to the casing in response to temperature-induced dimensional changes of at least a portion of the at least one TE module or at least a portion of the casing.

In certain embodiments, the TEG assembly further comprises a first region and a second region. The first region contains a first working fluid in thermal communication with the at least one TE module. The first region is bounded at least in part by the at least one support fixture and the casing. The second region is thermally insulated from the first region, the second region bounded at least in part by the at least one support fixture and the casing. For example, the second region can contain at least one electrical conduit in electrical communication with the at least one TE module. For another example, the second region can contain at least one second working fluid conduit in fluidic communication with the at least one TE module.

In certain embodiments, the at least one support fixture comprises at least one flexible structure configured to flex in response to the temperature-induced dimensional changes to reduce stress transferred to the at least one TE module. For example, the at least one support fixture can comprise at least one metal sheet and the at least one flexible structure comprises at least one bend or at least one fold of the at least one metal sheet.

In certain embodiments, the first portion of the at least one support fixture is press-fit to the at least one TE module. For example, the second portion of the at least one support fixture can be rigidly coupled to the casing. For another example, the at least one support fixture can comprise at least one hole and the at least one portion of the at least one TE module is press-fit into the at least one hole. The at least one portion of the at least one TE module can comprise a cylindrical portion of the at least one TE module or a conical portion of the at least one TE module.

In certain embodiments, the at least one portion of the at least one TE module is configured to slide axially relative to the at least one support fixture in response to the temperature-induced dimensional changes. In certain embodiments, the at least one support fixture comprises at least one fiber mat configured to apply a holding pressure to the at least one TE module or at least one wire mesh ring configured to apply a holding pressure to the at least one TE module.

In certain embodiments, gas can pass between the at least one support fixture and the at least one TE module from a first region on a first side of the at least one support fixture to a second region on a second side of the at least one support fixture, and gas cannot pass between the at least one support fixture and the casing from the first region to the second region. For example, the first region can contain a first working fluid in thermal communication with the at least one TE module.

In certain embodiments, a method of fabricating a thermoelectric generator (TEG) assembly is provided. The method comprises mechanically coupling at least one support fixture to a casing configured to contain at least one thermoelectric (TE) module. The method further comprises mechanically coupling the at least one TE module to the at least one support fixture. At least one portion of the at least one TE module is configured to move relative to the casing in response to temperature-induced dimensional changes of at least a portion of the TEG assembly.

In certain embodiments, mechanically coupling the at least one support fixture to the casing comprises rigidly coupling the at least one support fixture to the at least one TE module. In certain embodiments, the at least one support fixture comprises at least one flexible structure configured to flex in response to the temperature-induced dimensional changes to reduce stress transferred to the at least one TE module. For example, the at least one support fixture can comprise at least one metal sheet and the at least one flexible structure comprises at least one bend or at least one fold of the at least one metal sheet.

In certain embodiments, mechanically coupling the at least one TE module to the at least one support fixture comprises press-fitting the at least one portion of the at least one TE module to the at least one support fixture. For example, press-fitting can comprise press-fitting the at least one portion of the at least one TE module into a corresponding at least one hole of the at least one support fixture. In certain embodiments, upon said mechanically coupling the at least one TE module to the at least one support fixture, the at least one TE module can slide axially relative to the at least one support fixture in response to the temperature-induced dimensional changes.

The paragraphs above recite various features and configurations of one or more of a thermoelectric assembly, a thermoelectric module, or a thermoelectric system, that have been contemplated by the inventors. It is to be understood that the inventors have also contemplated thermoelectric assemblies, thermoelectric modules, and thermoelectric systems which comprise combinations of these features and configurations from the above paragraphs, as well as thermoelectric assemblies, thermoelectric modules, and thermoelectric systems which comprise combinations of these features and configurations from the above paragraphs with other features and configurations disclosed in the following paragraphs.

### BRIEF DESCRIPTION OF THE DRAWINGS

Various embodiments are depicted in the accompanying drawings for illustrative purposes, and should in no way be interpreted as limiting the scope of the thermoelectric assemblies or systems described herein. In addition, various features of different disclosed embodiments can be combined with one another to form additional embodiments, which are part of this disclosure. Any feature or structure can be removed, altered, or omitted. Throughout the drawings, reference numbers may be reused to indicate correspondence between reference elements.

FIG. 1 schematically illustrates an example thermoelectric generator assembly with fluid flow generally perpendicular to the plane of the figure in accordance with certain embodiments described herein.

FIG. 2 schematically illustrates a detailed view of an example support fixture in accordance with certain embodiments described herein.

FIG. 3 schematically illustrates a detailed view of a portion of the example thermoelectric generator assembly of FIG. 1 in accordance with certain embodiments described herein.

FIG. 4 schematically illustrates another example thermoelectric generator assembly with fluid flow generally perpendicular to the plane of the figure in accordance with certain embodiments described herein.

FIG. 5 is a flow diagram of an example method of fabricating a TEG assembly in accordance with certain embodiments described herein.

### DETAILED DESCRIPTION

Although certain embodiments and examples are disclosed herein, the subject matter extends beyond the examples in the specifically disclosed embodiments to other alternative embodiments and/or uses, and to modifications and equivalents thereof. Thus, the scope of the claims appended hereto is not limited by any of the particular embodiments described below. For example, in any method or process disclosed herein, the acts or operations of the method or process may be performed in any suitable sequence and are not necessarily limited to any particular disclosed sequence. Various operations may be described as multiple discrete operations in turn, in a manner that may be helpful in understanding certain embodiments; however, the order of description should not be construed to imply that these operations are order dependent. Additionally, the structures, systems, and/or devices described herein may be embodied as integrated components or as separate components. For purposes of comparing various embodiments, certain aspects and advantages of these embodiments are described. Not necessarily all such aspects or advantages are achieved by any particular embodiment. Thus, for example, various embodiments may be carried out in a manner that achieves or optimizes one advantage or group of advantages as taught herein without necessarily achieving other aspects or advantages as may also be taught or suggested herein.

A thermoelectric system as described herein can be a thermoelectric generator (TEG) assembly which uses the temperature difference between two fluids, two solids (e.g., rods), or a solid and a fluid to produce electrical power via thermoelectric materials. Each of the fluids can be liquid, gas, or a combination of the two, and the two fluids can both be liquid, both be gas, or one can be liquid and the other can be gas. Alternatively, a thermoelectric system as described herein can comprise a heater, cooler, or both which serves as a solid state heat pump used to move heat from one surface to another, thereby creating a temperature difference between the two surfaces via the thermoelectric materials. Each of the surfaces can be in thermal communication with or comprise a solid, a liquid, a gas, or a combination of two or more of a solid, a liquid, and a gas, and the two surfaces can both be in thermal communication with a solid, both be in thermal communication with a liquid, both be in thermal communication with a gas, or one can be in thermal communication with a material selected from a solid, a liquid, and a gas, and the other can be in thermal communication with a material selected from the other two of a solid, a liquid, and a gas.

The term “thermal communication” is used herein in its broad and ordinary sense, describing two or more components that are configured to allow heat transfer from one component to another. For example, such thermal communication can be achieved, without loss of generality, by snug contact between surfaces at an interface; one or more heat transfer materials or devices between surfaces; a connection between solid surfaces using a thermally conductive material system, wherein such a system can include pads, thermal grease, paste, one or more working fluids, or other structures with high thermal conductivity between the surfaces (e.g., heat exchangers); other suitable structures; or combinations of structures. Substantial thermal communication can take place between surfaces that are directly connected (e.g., contact each other) or indirectly connected via one or more interface materials.

As used herein, the terms “shunt” and “heat exchanger” have their broadest reasonable interpretation, including but not limited to a component (e.g., a thermally conductive device or material) that allows heat to flow from one portion of the component to another portion of the component. Shunts can be in thermal communication with one or more thermoelectric materials (e.g., one or more thermoelectric elements) and in thermal communication with one or more heat exchangers of the thermoelectric assembly or system. Shunts described herein can also be electrically conductive and in electrical communication with the one or more thermoelectric materials so as to also allow electrical current to flow from one portion of the shunt to another portion of the shunt (e.g., thereby providing electrical communication between multiple thermoelectric materials or elements). Heat exchangers (e.g., tubes and/or conduits) can be in thermal communication with the one or more shunts and one or more working fluids of the thermoelectric assembly or system. Various configurations of one or more shunts and one or more heat exchangers can be used (e.g., one or more shunts and one or more heat exchangers can be portions of the same unitary element, one or more shunts can be in electrical communication with one or more heat exchangers, one or more shunts can be electrically isolated from one or more heat exchangers, one or more shunts can be in direct thermal communication with the thermoelectric elements, one or more shunts can be in direct thermal communication with the one or more heat exchangers, an intervening material can be positioned between the one or more shunts and the one or more heat exchangers). Furthermore, as used herein, the words “cold,” “hot,” “cooler,” “hotter” and the like are relative terms, and do not signify a particular temperature or temperature range.

In some embodiments as discussed herein, the TEG assembly can comprise at least one “cartridge-based thermoelectric system” or “cartridge” as disclosed in U.S. Pat. Appl. Publ. No. 2013/0104953 or U.S. patent application Ser. No. 13/794,453. The cartridge is configured to apply a temperature differential across an array of thermoelectric elements of the cartridge in accordance with certain embodiments described herein. FIG. 6B of U.S. Pat. Appl. Publ. No. 2013/0104953 illustrates a perspective cross-sectional view of an example cartridge compatible with certain embodiments described herein. The cartridge of this figure includes an anodized aluminum “cold side” tube or conduit which is in thermal communication with a plurality of thermoelectric elements and a plurality of “hot side” heat transfer assemblies in thermal communication with the plurality of thermoelectric elements, such that a temperature differential is applied across the thermoelectric elements. As described in certain configurations, the “hot side” heat transfer assemblies can have a first working fluid (e.g., gas or vapor) flowing across the “hot side” heat transfer assemblies and the “cold side” tube can have a second working fluid (e.g., water) flowing through it.

The TEG assembly can include a single TE module (e.g., a single TE cartridge) or a group of TE modules (e.g., a group of TE cartridges), depending on usage, power output, heating/cooling capacity, coefficient of performance (COP) or voltage. Although the examples described herein may be described in connection with either a power generator or a heating/cooling system, the described features can be utilized with either a power generator or a heating/cooling system. As used herein, the term “TE cartridge” has its broadest reasonable interpretation, including but not limited to, the example thermoelectric assemblies and TE cartridges that are compatible with certain embodiments described herein disclosed in currently-pending U.S. Pat. Appl. Publ. No. 2013/0104953, filed Jun. 5, 2012 and U.S. patent application Ser. No. 13/794,453, filed Mar. 11, 2013, each of which is incorporated in its entirety by reference herein.

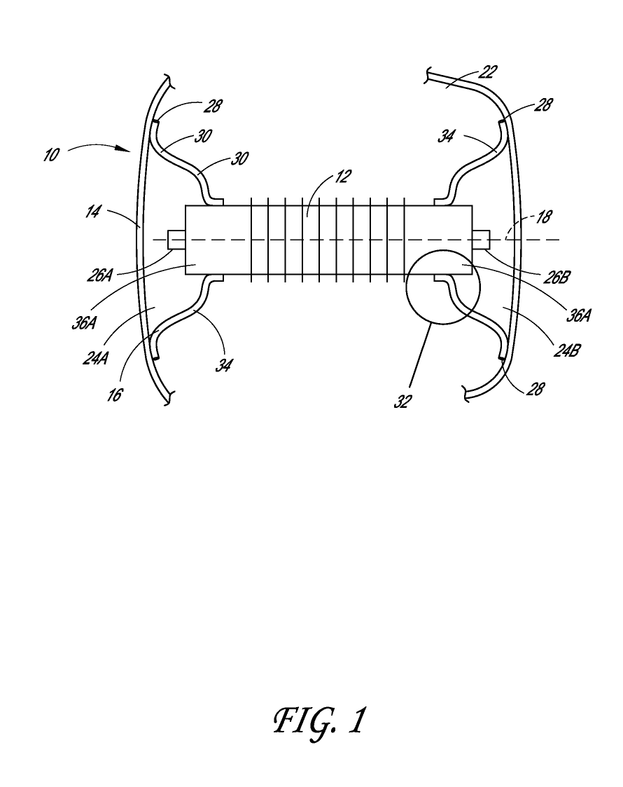

FIG. 1 schematically illustrates an example TEG assembly 10 with fluid flow generally perpendicular to the plane of the figure in accordance with certain embodiments described herein. As illustrated in FIG. 1, the TEG assembly 10 comprises at least one thermoelectric (TE) module 12 and a casing 14 containing the at least one TE module 12. The TEG assembly 10 further comprises at least one support fixture 16 mechanically coupling the at least one TE module 12 to the casing 14. The at least one support fixture 16 is coupled to the at least one TE module 12. At least one portion of the at least one TE module 12 is configured to move relative to the casing 14 in response to temperature-induced dimensional changes (e.g., of at least a portion of the at least one TE module 12, at least a portion of the casing 14, or both).

In certain embodiments described herein, the at least one TE module 12 can comprise at least one TE cartridge. As discussed above, examples of TE cartridges compatible with certain embodiments described herein are described in U.S. patent application Ser. No. 13/489,237, filed Jun. 5, 2012, and U.S. patent application Ser. No. 13/794,453, filed Mar. 11, 2013. In certain embodiments, the at least one TE module 12 is elongate in at least one direction. For example, the at least one TE module 12 can be elongate in an axial direction 18, can be generally cylindrically symmetric about the axial direction 18, and can have a diameter perpendicular to the axial direction 18, as schematically illustrated by FIG. 1. In another example, the at least one TE module 12 can be generally flat (e.g., elongate in at least two axial directions which are generally planar to one another) and can have a width (e.g., in a direction perpendicular to the at least two axial directions). The at least one TE module 12 can comprise at least one portion (e.g., a central portion of the at least one TE module 12, one or more portions spaced away from the central portion of the at least one TE module 12, one or more ends) configured to be mechanically coupled to the at least one support fixture 16. For example, the at least one TE module 12 can comprise two end-caps 20, as described more fully below.

In certain embodiments described herein, the casing 14 comprises a housing configured to hold (e.g., contain) the at least one TE module 12 during operation of the TEG assembly 10. The casing 14 can at least partially bound at least one region 22 within the casing 14, and the at least one TE module 12 can be partially or wholly within the at least one region 22. In certain embodiments, the casing 14 seals the at least one region 22 from the surrounding environment. For example, the casing 14 can provide a gas-tight seal between the at least one region 22 and the surrounding environment. The casing 14 can comprise metal (e.g., steel, aluminum) or other material configured to be mechanically coupled to the at least one support fixture 16, as described more fully below.

In certain embodiments, the casing 14 comprises one or more fluid ports configured to allow at least one working fluid to flow into the casing 14 and one or more fluid ports configured to allow the at least one working fluid to flow out of the casing 14. The casing 14 can also comprise one or more fluid conduits configured to allow the at least one working fluid to flow through the casing 14 and to be in thermal communication with the at least one TE module 12. For example, as schematically shown in FIG. 1, the TEG assembly 10 comprises at least one first region 22 and at least one second region 24 (e.g., second regions 24A, 24B). The at least one first region 22 can contain a first working fluid in thermal communication with the at least one TE module 12, and the at least one first region 22 can be bounded at least in part by the at least one support fixture 16 and the casing 14. The at least one second region 24 can be thermally insulated from the at least one first region 22, and the at least one second region 24 can be bounded at least in part by the at least one support fixture 16 and the casing 14.

In certain such embodiments, the casing 14 is configured to allow the first working fluid (e.g., exhaust gas from an engine) to flow through the at least one first region 22 (e.g., from a gas inlet port to a gas outlet port) in a direction generally perpendicular to FIG. 1 and in thermal communication with a hot side of the at least one TE module 12. As another example, as schematically shown in FIG. 1, the casing 14 is configured to allow a second working fluid (e.g., cooling liquid) to flow through the second region 24A, through an inlet 26A of the at least one TE module 12, in thermal communication with a cold side of the at least one TE module 12, through an outlet 26B of the at least one TE module 12, and through the second region 24B. Thus, the at least one second region 24 can contain at least one second working fluid conduit in fluidic communication with the at least one TE module 12. The at least one second region 24 can contain at least one electrical conduit in electrical communication with the at least one TE module 12.

The at least one support fixture 16 can be mechanically coupled to the casing 14. For example, as schematically illustrated in FIG. 1, the at least one support fixture 16 can be rigidly affixed to a portion of the casing 16 by a coupling structure 28 (e.g., by one or more welds, brazes, or other types of rigid couplings). In certain other embodiments, the at least one support fixture 16 is mechanically coupled to the casing 14 by a flexible or resilient structure. For example, the at leat one support fixture 16 can comprise at least one flexible structure 30 (e.g., at least one bend, at least one fold), described more fully below, that is configured to flex in response to the temperature-induced dimensional changes to reduce stress transferred to the at least one TE module 12.

In certain embodiments, the one or more TE modules 12 can be held in place or coupled to the at least one support fixture 16 using various types of structures. In certain embodiments, the at least one support fixture 16 is mechanically coupled to the at least one TE module 12 (e.g., in a region 32 as schematically illustrated by FIG. 1) such that at least a portion of the at least one TE module 12 can move relative to the casing 14 in response to temperature-induced dimensional changes among the various components of the TEG assembly 10, while remaining mechanically coupled to the at least one support fixture 16. For example, the at least one support fixture 16 can be configured to allow for (e.g., to make possible, to compensate for, or to otherwise take into account) at least one dimensional variation or change due to thermal expansion or contraction of at least a portion of the TEG assembly 10 during operation of the TEG assembly 10 which may include variations of temperature. The dimensional variations or changes can include, but are not limited to: the length of the at least one TE module 12 (e.g., in an axial direction of the at least one TE module 12), the width (e.g., diameter) of the at least one portion (e.g., end-caps 20) of the one or more TE modules 12 mechanically coupled to the at least one support fixture 16, one or more dimensions of the casing 14, and the distance between at least a portion of the at least one TE module 12 and at least a portion of the casing 14.

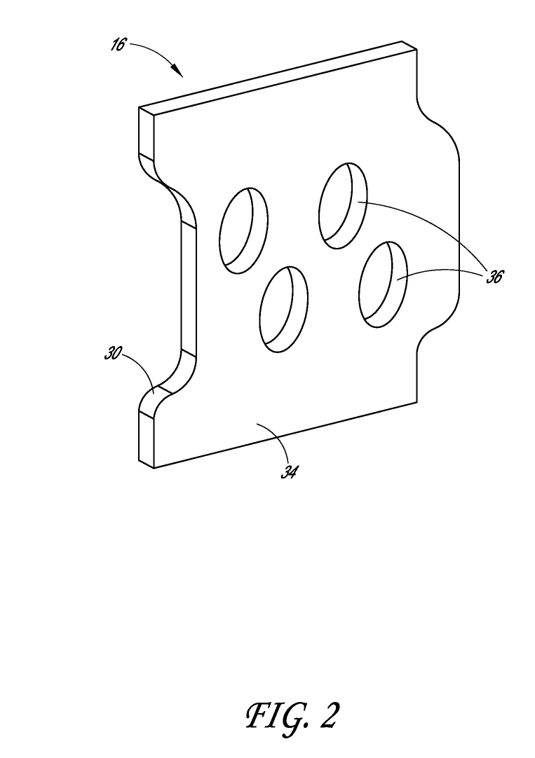

FIG. 2 schematically illustrates a detailed view of an example support fixture 16 in accordance with certain embodiments described herein. For example, in certain embodiments, the at least one support fixture 16 comprises at least one flexible structure 30 configured to flex in response to the temperature-induced dimensional changes to reduce stress transferred to the at least one TE module 12. The at least one flexible structure 30 can have sufficient flexibility in response to temperature-induced dimensional changes of at least a portion of the TEG assembly 10 so that the amount of stress applied to the at least one TE module 12 by the dimensional changes does not rise to a level which damages the at least one TE module 12. For example, the at least one flexible structure 30 can comprise at least one stress-responsive structure (e.g., at least one bend, at least one fold) configured to flex and to reduce (e.g., prevent, minimize, avoid) thermo-mechanical stress being applied to the at least one TE module 12 from temperature-induced dimensional changes of at least a portion of the TEG assembly 10.

For example, in some embodiments, the at least one support fixture 16 comprises at least one metal sheet 34 and the at least one flexible structure 30 comprises at least one bend or at least one fold of the at least one metal sheet 34, as schematically illustrated in FIGS. 1 and 2. The at least one metal sheet 34 can have sufficient rigidity to retain the at least one TE module 12 in an operational location. The at least one bend or the at least one fold can have sufficient flexibility to allow at least a portion of the at least one metal sheet 34 to move (e.g., flex, twist, bend) in response to temperature-induced dimensional changes of at least a portion of the TEG assembly 10 while the amount of stress applied to the at least one TE module 12 by the dimensional changes does not rise to a level which damages the at least one TE module 12. In certain embodiments, the at least one TE module 12 remains in the operational location despite the dimensional changes.

For another example, in certain embodiments in which the at least one TE module 12 is elongate in at least one axial direction 18 (e.g., as schematically illustrated in FIG. 1), the at least one support fixture 16 is configured to allow the one or more TE modules 12 to slide axially (e.g., to slide in the axial direction 18) relative to the at least one support fixture 16. The at least one support fixture 16 can be configured to hold the at least one TE module 12 without utilizing any fixed coupling (e.g., direct welding) of the at least one support fixture 16 to the at least one TE module 12. For example, as schematically illustrated in FIGS. 1 and 2, the at least one support fixture 16 can comprise one or more metal sheets 34 and can comprise at least one portion (e.g., at least one hole 36) configured to be slidably coupled to a corresponding portion of the at least one TE module 12. For example, the portion of the at least one TE module 12 can fit into the at least one hole 36 such that the at least one TE module 12 can slide relative to the at least one support fixture 16 while remaining within the at least one hole 36.

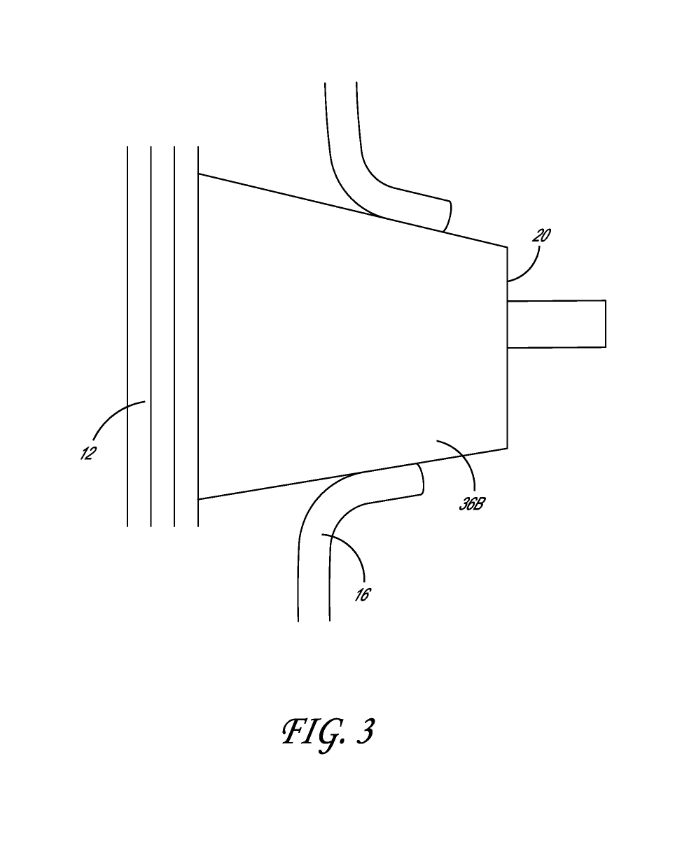

In certain embodiments, the at least one support fixture 16 can comprise a first portion press-fit to the at least one TE module 12. In certain such embodiments, the at least one support fixture 16 can further comprise a second portion rigidly coupled to the casing 14, as described above. The first portion of the at least one TE module can include, but is not limited to, at least one cylindrical portion 36A of the at least one TE module 12, or at least one conical portion 36B of the at least one TE module 12. For example, FIG. 1 schematically illustrates two cylindrical portions 36A at corresponding ends of the at least one TE module 12, and FIG. 3 schematically illustrates a conical portion 36B at an end of the at least one TE module 12.

In certain embodiments, the at least one support fixture 16 further comprises at least one structure (e.g., at least one fiber mat, at least one wire mesh, at least one wire mesh ring) configured to apply a holding pressure to the at least one TE module 12. The at least one structure can provide a slidable coupling to the at least one TE module 12 which can be inelastic or elastic. For example, the at least one support fixture 16 can comprise a fiber mat within a hole 36 of the metal sheet 34 described above and contacting the portion of the at least one TE module 12 within the hole 36, with the fiber mat configured to allow the at least one TE module 12 to slide within the hole 36 in response to the temperature-induces dimensional changes. For another example, the at least one support fixture 16 can comprise a wire mesh ring within the hole 36 of the metal sheet 34 described above and contacting the portion of the at least one TE module 12 within the hole 36, with the wire mesh ring configured to allow the at least one TE module 12 to slide within the hole 36 in response to the temperature-induces dimensional changes. In certain embodiments in which the TEG assembly 10 is a component of an exhaust system, such fiber mats or wire mesh rings, or other structures or methods used to couple the at least one support fixture 16 to the at least one TE module 12, can be compatible with the exhaust system design. Advantageously, in certain embodiments, the at least one structure configured to apply the holding pressure to the at least one TE module 12 does not comprise welding directly to the at least one TE module 12, thereby avoiding unduly heating the at least one TE module 12 during fabrication of the TEG assembly 10.

As discussed above, in certain embodiments, the TEG assembly 10 comprises at least one first region 22 and at least one second region 24 (e.g., second regions 24A, 24B). The at least one first region 22 can contain a first working fluid in thermal communication with the at least one TE module 12, and the at least one first region 22 can be bounded at least in part by the at least one support fixture 16 and the casing 14. The at least one second region 24 can be bounded at least in part by the at least one support fixture 16 and the casing 14. In certain embodiments, gas can pass between the at least one support fixture 16 and the at least one TE module 12 from the first region 22 on a first side of the at least one support fixture 16 to the second region 24 on a second side of the at least one support fixture 16. For example, the coupling between the at least one support fixture 16 and the at least one TE module 12 is not gas-tight. In certain other embodiments, the coupling between the at least one support fixture 16 and the at least one TE module 12 is gas-tight.

In certain embodiments, gas cannot pass between the at least one support fixture 16 and the casing 14 from the first region 22 to the second region 24. For example, the coupling structure 28 between the at least one support fixture 16 and the casing 14 can be gas-tight. In some embodiments, as schematically shown in FIG. 1, the coupling structure 28 comprises an outer edge (e.g., an outer perimeter) of the at least one support fixture 16 which can form a gas-tight seal with the casing 14 (e.g., using weld seams between the outer edge of the at least one support fixture 16 and the casing 14) of the TEG assembly 10. In certain such embodiments, the gas-tight seal between the at least one support fixture 16 and the casing 14 (e.g., at the outer edge of the at least one support fixture 16) can serve as a gas-tight seal between each TE module 12 of the at least one TE module 12 and the casing 14.

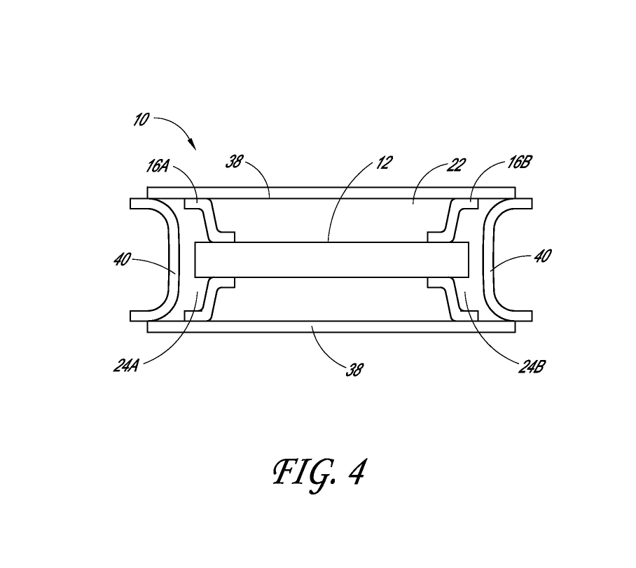

FIG. 4 schematically illustrates another example TEG assembly 10 with fluid flow generally perpendicular to the plane of the figure in accordance with certain embodiments described herein. Similarly to the example TEG assembly 10 of FIG. 1, the TEG assembly 10 of FIG. 4 comprises a first region 22 containing a first working fluid in thermal communication with the at least one TE module 12. The first region 22 is bounded at least in part by the at least one support fixture 16 and the casing 14. The TEG assembly 10 further comprises at least one second region 24 which can be thermally insulated from the first region 22. The at least one second region 24 is bounded at least in part by the at least one support fixture 16 and the casing 14. As schematically illustrated by FIG. 4, in some embodiments, the TEG assembly 10 comprises at least one first region 22 (e.g., central chamber, room, space, area) and at least one second region 24A, 24B (e.g., side chambers, rooms, spaces, areas) bounded at least in part by the at least one support fixture 16A, 16B, In certain embodiments, the at least one second region 24A, 24B can be at least partially thermally insulated from the at least one first region 22. For example, the TEG assembly 10 can comprise at least one thermally insulating surface comprising a thermally insulating material and configured to at least partially thermally insulate the at least one second region 24A, 24B from the gas flowing through the at least one first region 22. For example, the at least one thermally insulating surface be located inside the at least one second region 24A, 24B. For another example, the at least one thermally insulating surface can comprise a surface of the at least one support fixture 16 configured to further decrease the temperature within the at least one second region 24A, 24B. The at least one second region 24A, 24B can also be configured to accommodate water pipes and electrical terminals or conduits used for operation of the at least one TE module 12, since the at least one second region 24A, 24B can have a much lower temperature than does the at least one first region 22 when used as a main fluid conduit through which hot fluid (e.g., gas, liquid, gas and liquid) can flow in thermal communication with a hot side of the at least one TE module 12.

As schematically illustrated by FIG. 4, the casing 14 of the TEG assembly 10 can comprise one or more portions mechanically coupled (e.g., welded) to one another. For example, the TEG assembly 10 can comprise one or more metal sheets 38 coupled (e.g., welded, brazed) to the at least one support fixture 16 and can comprise one or more side baffles 40 mechanically coupled (e.g., welded, brazed) to the one or more metal sheets 38. In certain such embodiments, the at least one first region 22 is at least partially bounded by the at least one support fixture 16 and the metal sheets 38, and the at least one second region 24 is at least partially bounded by the at least one support fixture 16 and the side baffles 40.

As discussed above with regard to FIG. 1, in certain embodiments of the TEG assembly 10 schematically illustrated in FIG. 4, the coupling of the at least one support fixture 16 and the at least one TE module 12 is not gas-tight, while in certain other embodiments, the coupling of the at least one support fixture 16 and the at least one TE module 12 is gas-tight. Furthermore, as discussed above with regard to FIG. 1, in certain embodiments of the TEG assembly 10 schematically illustrated in FIG. 4, there is a gas-tight seal or coupling between the casing 14 and a portion of the at least one support fixture 16. For example, in some embodiments, a first working fluid (e.g., gas, liquid, or both gas and liquid) cannot pass between the at least one support fixture 16 and the casing 14 (e.g., from the at least one first region 22 to the at least one second region 24A, 24B), and a second working fluid (e.g., gas, liquid, or both gas and liquid) can pass through the at least one TE module 12 from a second region 24A on a first side of the at least one support fixture 16A to a second region 24B on a second side of the at least one support fixture 16B.

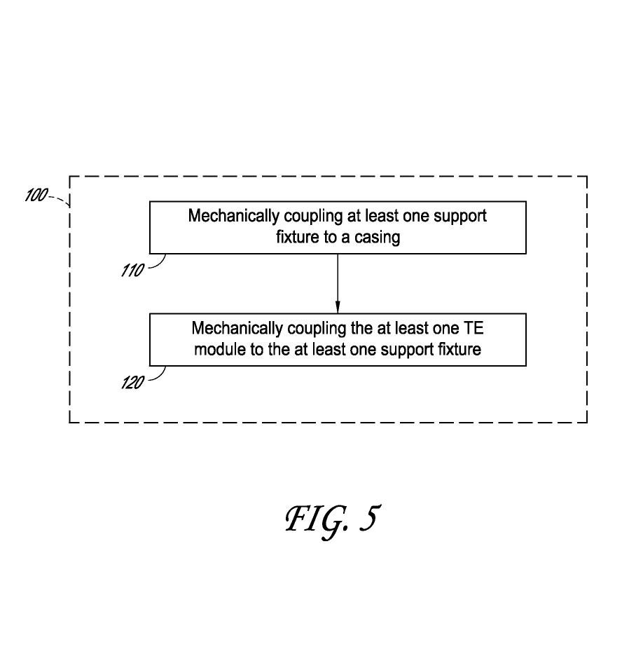

A method 100 for fabricating a TEG assembly 10 according to certain embodiments described herein is illustrated in the flow diagram of FIG. 5. While the method 100 is described below by referencing the structures described above, the method 100 may also be practiced using other structures. In an operational block 110, the method 100 comprises mechanically coupling at least one support fixture 16 to a casing 14 configured to contain at least one thermoelectric (TE) module 12. In an operational block 120, the method 100 further comprises mechanically coupling the at least one TE module 12 to the at least one support fixture 16. At least one portion of the at least one TE module 12 is configured to move relative to the casing 14 in response to temperature-induced dimensional changes of at least a portion of the TEG assembly 10 (e.g., of at least a portion of the at least one TE module 12, of at least a portion of the casing 14, or both).

In some embodiments, mechanically coupling the at least one support fixture 16 to the casing 14 comprises rigidly coupling the at least one support fixture 16 to the at least one TE module 12. In some embodiments, the at least one support fixture 16 comprises at least one flexible structure 30 configured to flex in response to the temperature-induced dimensional changes to reduce stress transferred to the at least one TE module 12.

In some embodiments, the at least one support fixture 16 comprises at least one metal sheet 34 and the at least one flexible structure 30 comprises at least one bend or at least one fold of the at least one metal sheet 34. In some embodiments, mechanically coupling the at least one TE module 12 to the at least one support fixture 16 comprises press-fitting the at least one portion of the at least one TE module 12 to the at least one support fixture 16.

In some embodiments, press-fitting comprises press-fitting the at least one portion of the at least one TE module 12 into a corresponding at least one hole 24 of the at least one support fixture 16. In some embodiments, upon mechanically coupling the at least one TE module 12 to the at least one support fixture 16, the at least one TE module 12 can slide axially relative to the at least one support fixture 16 in response to the temperature-induced dimensional changes.

Certain embodiments described herein advantageously reduce the time, costs, and complexity of fabricating the TEG assembly 10 by avoiding welding directly to the at least one TE module 12. Certain embodiments described herein advantageously protect and insulate the water/electrical circuits (e.g., water pipes, electrical terminals) from excessive temperature by having these components located within the at least one second region 24 that is thermally insulated from the at least one first region 22 that comprises a gas flow conduit. Certain embodiments described herein advantageously allow the TEG assembly 10 to expand and contract with temperature so as to reduce thermo-mechanical stresses experienced by the at least one TE module 12.

In certain embodiments, the TEG assembly 10 is integrated into an acoustic dampening component (e.g., muffler) of an engine exhaust system. For example, a TEG assembly 10 can be integrated into a muffler as described in U.S. patent application Ser. No. 13/954,786, filed Jul. 30, 2013 and incorporated in its entirety by reference herein. In particular, FIGS. 6, 7, 8, and 9A-9C and the corresponding text of U.S. patent application Ser. No. 13/954,786 disclose various configurations in which a TEG assembly 10 can be utilized in a muffler, and these configurations are incorporated in their entirety by reference herein. In certain embodiments, the TEG assembly 10 described herein can be used in place of the TEG assemblies disclosed by U.S. patent application Ser. No. 13/954,786. In certain embodiments, the at least one support fixture 16 can be mechanically coupled to the muffler baffles (e.g., muffler baffles 61, 63 of FIGS. 6, 7, and 8 of U.S. patent application Ser. No. 13/954,786) thereby supporting the at least one TE module 12 in a flowpath of the hot exhaust gas flowing through the muffler such that the hot side of the at least one TE module 12 is in thermal communication with the hot exhaust gas. In certain embodiments, the at least one support fixture 16 can be mechanically coupled to the outer shell and can serve as an inner shell (e.g., the outer shell 81 and the inner shell 79 of FIGS. 9A-9C of U.S. patent application Ser. No. 13/954,786) thereby supporting the at least one TE module 12 in a flowpath of the hot exhaust gas flowing through the muffler such that the hot side of the at least one TE module 12 in the at least one first region 22 is in thermal communication with the hot exhaust gas. In addition, the at least one second region 24 can be thermally insulated from the at least one first region 22.

Discussion of the various embodiments herein has generally followed the embodiments schematically illustrated in the figures. However, it is contemplated that the particular features, structures, or characteristics of any embodiments discussed herein may be combined in any suitable manner in one or more separate embodiments not expressly illustrated or described. In many cases, structures that are described or illustrated as unitary or contiguous can be separated while still performing the function(s) of the unitary structure. In many instances, structures that are described or illustrated as separate can be joined or combined while still performing the function(s) of the separated structures.

Various embodiments have been described above. Although the inventions have been described with reference to these specific embodiments, the descriptions are intended to be illustrative and are not intended to be limiting. Various modifications and applications may occur to those skilled in the art without departing from the spirit and scope of the inventions as defined in the appended claims.

What is claimed is:

1. A thermoelectric generator (TEG) assembly comprising:
at least one thermoelectric (TE) module;
a casing containing the at least one TE module; and
at least one support fixture mechanically coupling the at least one TE module to the casing, the at least one support fixture coupled to the at least one TE module, at least one portion of the at least one TE module configured to move relative to the casing in response to temperature-induced dimensional changes of at least a portion of the at least one TE module or at least a portion of the casing.

2. The TEG assembly of claim 1, further comprising:
a first region containing a first working fluid in thermal communication with the at least one TE module, the first region bounded at least in part by the at least one support fixture and the casing; and
a second region thermally insulated from the first region, the second region bounded at least in part by the at least one support fixture and the casing.

3. The TEG assembly of claim 2, wherein the second region contains at least one electrical conduit in electrical communication with the at least one TE module.

4. The TEG assembly of claim 2, wherein the second region contains at least one second working fluid conduit in fluidic communication with the at least one TE module.

5. The TEG assembly of claim 1, wherein the at least one support fixture comprises at least one flexible structure configured to flex in response to the temperature-induced dimensional changes to reduce stress transferred to the at least one TE module.

6. The TEG assembly of claim 5, wherein the at least one support fixture comprises at least one metal sheet and the at least one flexible structure comprises at least one bend or at least one fold of the at least one metal sheet.

7. The TEG assembly of claim 1, wherein a first portion of the at least one support fixture is press-fit to the at least one TE module.

8. The TEG assembly of claim 7, wherein a second portion of the at least one support fixture is rigidly coupled to the casing.

9. The TEG assembly of claim 7, wherein the at least one support fixture comprises at least one hole and the at least one portion of the at least one TE module is press-fit into the at least one hole.

10. The TEG assembly of claim 9, wherein the at least one portion of the at least one TE module comprises a cylindrical portion of the at least one TE module.

11. The TEG assembly of claim 9, wherein the at least one portion of the at least one TE module comprises a conical portion of the at least one TE module.

12. The TEG assembly of claim 7, wherein the at least one portion of the at least one TE module is configured to slide axially relative to the at least one support fixture in response to the temperature-induced dimensional changes.

13. The TEG assembly of claim 7, wherein the at least one support fixture comprises at least one fiber mat configured to apply a holding pressure to the at least one TE module.

14. The TEG assembly of claim 7, wherein the at least one support fixture comprises at least one wire mesh ring configured to apply a holding pressure to the at least one TE module.

15. The TEG assembly of claim 1, wherein gas can pass between the at least one support fixture and the at least one TE module from a first region on a first side of the at least one support fixture to a second region on a second side of the at least one support fixture, and gas cannot pass between the at least one support fixture and the casing from the first region to the second region.

16. The TEG assembly of claim 15, wherein the first region contains a first working fluid in thermal communication with the at least one TE module.

17. A method of fabricating a thermoelectric generator (TEG) assembly, the method comprising:
mechanically coupling at least one support fixture to a casing configured to contain at least one thermoelectric (TE) module; and
mechanically coupling the at least one TE module to the at least one support fixture, at least one portion of the at least one TE module configured to move relative to the casing in response to temperature-induced dimensional changes of at least a portion of the TEG assembly.

18. The method of claim 17, wherein said mechanically coupling the at least one support fixture to the casing comprises rigidly coupling the at least one support fixture to the at least one TE module.

19. The method of claim 17, wherein the at least one support fixture comprises at least one flexible structure configured to flex in response to the temperature-induced dimensional changes to reduce stress transferred to the at least one TE module.

20. The method of claim 19, wherein the at least one support fixture comprises at least one metal sheet and the at least one flexible structure comprises at least one bend or at least one fold of the at least one metal sheet.

21. The method of claim 17, wherein said mechanically coupling the at least one TE module to the at least one support fixture comprises press-fitting the at least one portion of the at least one TE module to the at least one support fixture.

22. The method of claim 21, wherein said press-fitting comprises press-fitting the at least one portion of the at least one TE module into a corresponding at least one hole of the at least one support fixture.

23. The method of claim 17, wherein, upon said mechanically coupling the at least one TE module to the at least one support fixture, the at least one TE module can slide axially relative to the at least one support fixture in response to the temperature-induced dimensional changes.
